(19) United States
(12) Patent Application Publication
(10) Pub. No.: US 2014/0110682 A1
(43) Pub. Date: Apr. 24, 2014

(54) PIXEL STRUCTURE OF ELECTROLUMINESCENT DISPLAY PANEL

(71) Applicant: AU Optronics Corp., Hsin-Chu (TW)

(72) Inventor: Hung-Hsin Shih, Hsin-Chu (TW)

(21) Appl. No.: 13/921,202

(22) Filed: Jun. 18, 2013

(30) Foreign Application Priority Data
Oct. 22, 2012 (TW) 101138902

(51) Int. Cl. H01L 51/52

(52) U.S. Cl. CPC H01L 51/5203
USPC 257/40; 257/88

(57) ABSTRACT

A pixel structure of an electroluminescent display panel having a first sub-pixel region and a second sub-pixel region is disclosed. The pixel structure includes a first organic light emitting layer disposed in the first sub-pixel region and the second sub-pixel region. The first organic light emitting layer is a single layered organic light emitting layer made of one single organic light emitting material. A cavity length of the first sub-pixel region is shorter than a cavity length of the second sub-pixel region so as to enable the first sub-pixel region and the second sub-pixel region to respectively provide a first primary color light and a second primary color light. A peak wavelength of the second primary color light is larger than a peak wavelength of the first primary color light.

### BACKGROUND OF THE INVENTION

1. Field of the Invention

The present invention generally relates to a pixel structure of an electroluminescent display panel, and more particularly, to a pixel structure of an electroluminescent display panel, which includes an organic light emitting layer made of one single organic light emitting material and disposed in the corresponding sub-pixel regions with different cavity length so as to respectively generate different primary color lights.

2. Description of the Prior Art

Due to no needs of color filters, the capability of spontaneous light emission (without backlight module) and the advantage of low electricity consumption, electroluminescent display devices are highly expected to replace conventional liquid crystal display devices and become one of the mainstream techniques in the next generation apparatuses. In the field of the electroluminescent display devices, the technique for manufacturing organic light emitting diode displays is one of the relatively well-developed techniques in the current stage. Nowadays, white organic light emitting layers are mostly adopted in full color electroluminescent display panels to generate white light. The white light may be further split into three different primary lights, such as red light, green light and blue light through a color filter. In this way, the electroluminescent display panel can therefore provide full color display images. However, since the white light is produced via a wide spectrum light source, the saturation of the red light, the green light and the blue light filtered by the color filter are still not high enough, which causes relatively low color gamut. Furthermore, even if the color saturation can be improved by respectively disposing red organic light emitting layers, green organic light emitting layers and blue organic light emitting layers in different sub-pixel regions to generate the respective color light, the complexity of the manufacturing processes will be correspondingly increased since evaporation deposition is required for forming these organic light emitting layers with different colors, which needs several complex fine metal mask (FMM) processes. Additionally, this method also incurs other drawbacks, such as the mixture of color light and a low yield rate.

### SUMMARY OF THE INVENTION

One objective of the present invention is to provide a pixel structure of an electroluminescent display panel. By disposing organic light emitting layers composed of one single organic light emitting material in respective sub-pixel regions with different cavity lengths, different primary color lights can be respectively generated from different sub-pixel regions of the pixel structure of the electroluminescent display panel. In this way, the manufacturing processes and the configurations of the display can be simplified, which further lowers the manufacturing costs.

To this end, a pixel structure of an electroluminescent display panel is provided according to one preferred embodiment of the present invention. The pixel structure of the electroluminescent display panel has a first sub-pixel region and a second sub-pixel region. The pixel structure includes a first anode, a second anode, a first cathode, a second cathode and a first organic light emitting layer. The first anode and the first cathode are disposed in the first sub-pixel region. The second anode and the second cathode are disposed in the second sub-pixel region. The first organic light emitting layer is disposed in the first sub-pixel region and the second sub-pixel region. The first organic light emitting layer is a single layered organic light emitting layer. The first organic light emitting layer is made of one single organic light emitting material for the first sub-pixel region and the second sub-pixel region respectively generating a first primary color light and a second primary color light. A first micro cavity is formed between the first anode and the first cathode in the first sub-pixel region. A second micro cavity is formed between the second anode and the second cathode in the second sub-pixel region. A cavity length of the first micro cavity is shorter than a cavity length of the second micro cavity so as to enable the first sub-pixel region to provide the first primary color light and enable the second sub-pixel region to provide the second primary color light. A peak wavelength of the second primary color light is larger than a peak wavelength of the first primary color light.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram showing a pixel structure of an electroluminescent display panel according to the first preferred embodiment of the present invention.

FIG. 2 is a schematic diagram showing a wavelength spectrum of a pixel structure of an electroluminescent display panel according to the first preferred embodiment of the present invention.

FIG. 3 is a schematic diagram showing a pixel structure of an electroluminescent display panel according to the second preferred embodiment of the present invention.

FIG. 4 is a schematic diagram showing a pixel structure of an electroluminescent display panel according to the third preferred embodiment of the present invention.

FIG. 5 is a schematic diagram showing a pixel structure of an electroluminescent display panel according to the fourth preferred embodiment of the present invention.

FIG. 6 is a schematic diagram showing a pixel structure of an electroluminescent display panel according to the fifth preferred embodiment of the present invention.

FIG. 7 is a schematic diagram showing a pixel structure of an electroluminescent display panel according to the sixth preferred embodiment of the present invention.

### DETAILED DESCRIPTION

To provide a better understanding of the present invention to those skilled in the technology of the present invention, various preferred embodiments will be detailed as follows. The preferred embodiments of the present invention are illustrated in the accompanying drawings with numbered elements to elaborate the contents and effects to be achieved.

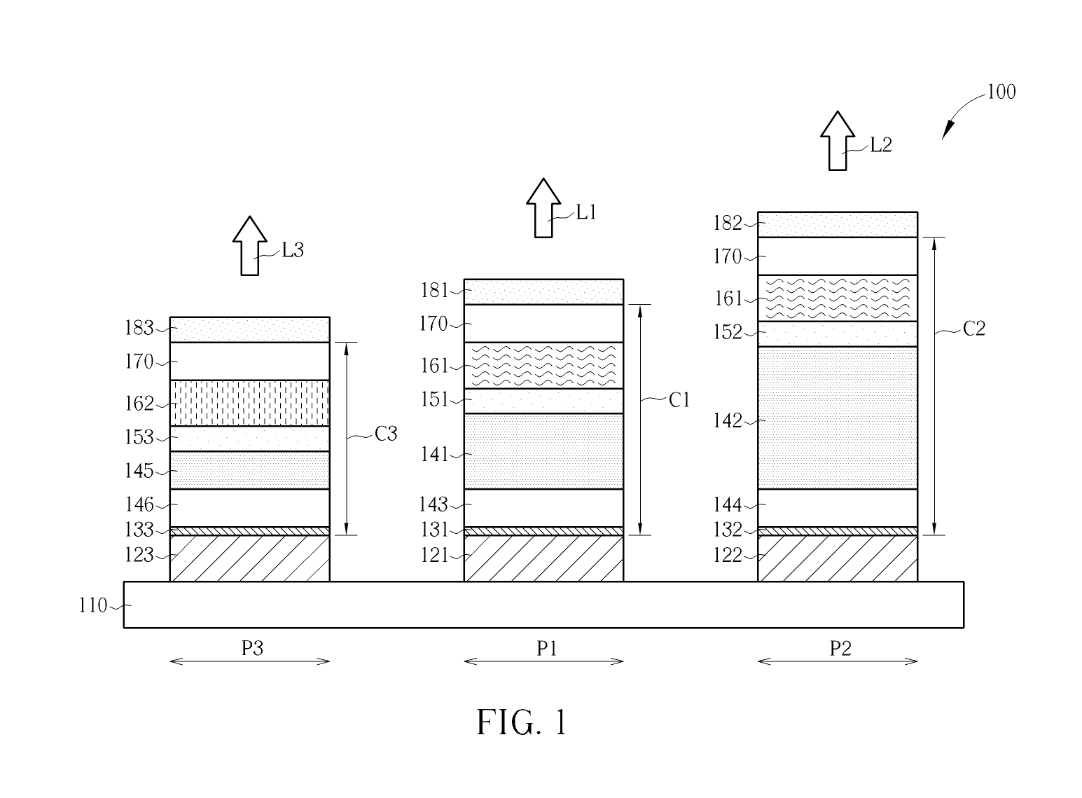

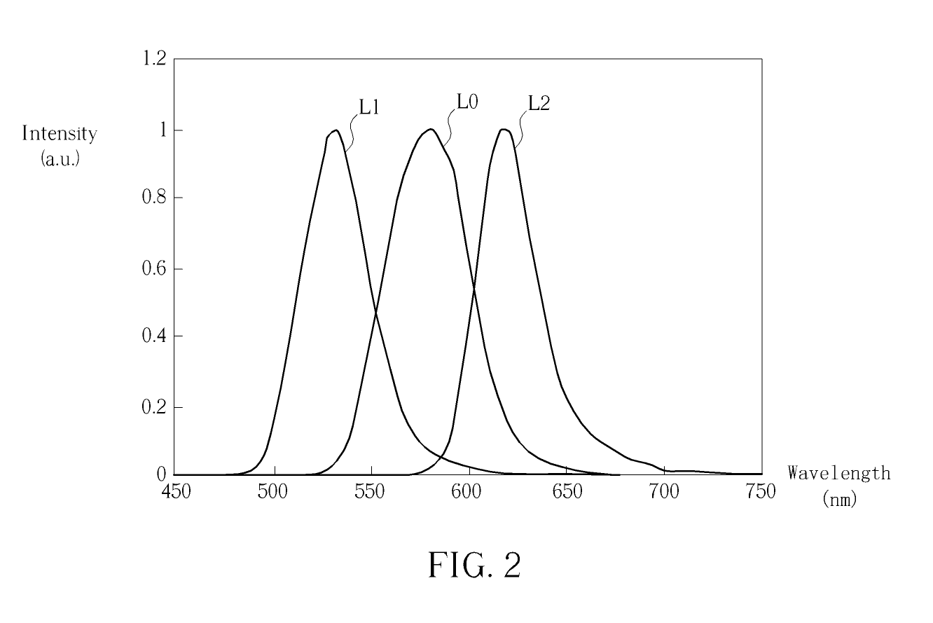

Please refer to FIG. 1 and FIG. 2. FIG. 1 is a schematic diagram showing a pixel structure of an electroluminescent display panel according to the first preferred embodiment of the present invention. FIG. 2 is a schematic diagram showing a wavelength spectrum of a pixel structure of an electroluminescent display panel according to the first preferred embodiment of the present invention. It is to be understood that the relative dimensions and sizes of various elements and components depicted in the figures do not reflect actual dimensions and are for illustrative purpose only. That is to say, the actual dimensions and sizes of various elements and components may be adjusted according to various design requirements.

As shown in FIG. 1, a pixel structure of an electroluminescent display panel 100 according to this embodiment includes a first sub-pixel region P1 and a second sub-pixel region P2. The pixel structure of the electroluminescent display panel 100 includes a first anode 121, a second anode 122, a first cathode 181, a second cathode 182 and a first organic light emitting layer 161. The first anode 121 and the first cathode 181 are disposed in the first sub-pixel region P1. The second anode 122 and the second cathode 182 are disposed in the second sub-pixel region P2. The first organic light emitting layer 161 are disposed in first sub-pixel region P1 and the second sub-pixel region P2. It should be noted that the first organic light emitting layer 161 is a single layered organic light emitting layer made of one single organic light emitting material. Through the first organic light emitting layer 161, first primary color light L1 and second primary color light L2 may be respectively generated from the first sub-pixel region P1 and the second sub-pixel region P2. A first micro cavity C1 is formed between the first anode 121 and the first cathode 181 in the first sub-pixel region P1. Similarly, a second micro cavity C2 is formed between the second anode 122 and the second cathode 182 in the second sub-pixel region P2. A cavity length of the first micro cavity C1 is shorter than a cavity length of the second micro cavity C2 so that the first sub-pixel region P1 and the second sub-pixel region P2 may be respectively enabled to provide the first primary color light L1 and the second primary color light L2.

As shown in FIG. 1 and FIG. 2, light L0 indicates an original color light emitted from the organic light emitting material of the first organic light emitting layer 161. According to this embodiment, the various micro cavity effects may be obtained by adjusting the respective cavity length in the first sub-pixel region P1 and the second sub-pixel region P2. As a result, the first primary color light L1 may be generated by the first sub-pixel region P1 and the second primary color light L2 may be generated by the second sub-pixel region P2. For example, the organic light emitting material of the first organic light emitting layer 161 according to this embodiment is preferably a yellow organic light emitting material. The first primary color light L1 are green light and the second primary color light L2 are red light, but not limited to this. A peak wavelength of the second primary color light L2 is larger than a peak wavelength of the first primary color light L1. Besides, a peak wavelength of the original color light L0 is between a peak wavelength of the second primary color light L2 and a peak wavelength of the first primary color light L1. Additionally, the peak wavelength of the yellow organic light emitting material according to this embodiment preferably substantially ranges from 575 nanometers to 595 nanometers, but not limited to this. Furthermore, the above mentioned yellow organic light emitting material is preferably chosen from a single organic light emitting material composed of the mixture of host material and dopant material. This single organic light emitting material can only emit one single color light itself. The host material described above is prferably selected from one of the group consisting of Alq₃ (Tris(8-hydroxy-quinolinato)aluminium), TpyPA (Tris [4-(pyrenyl)-phenyl]amine), MCP (1,3-bis(carbazol-9-yl)benzene), TCP (1,3,5-tris(carbazol-9-yl)benzene), CBP (4,4′-bis(carbazol-9-yl)biphenyl), TCTA (Tris(4-carbazoyl-9-ylphenyl)amine), CDBP (4,4′-bis(carbazol-9-yl)-2,2′-dimethylbiphenyl), 26DCzPPy (2,6-bis(3-(9H-carbazol-9-yl)phenyl)pyridine), 35DCzPPy (3,5-bis(3-(9H-carbazol-9-yl)phenyl)pyridine) or other suitable host material. The dopant material described above is preferably selected from one of the group consisting of DCM ((E)-2-(2-(4-(dimethylamino)styryl)-6-methyl-4H-pyran-4-ylidene)malononitrile), Rubrene (5,6,11,12-tetraphenylnaphthacene), Ir(2-phq)₃ (Tris(2-phenylquinoline)iridium(III)), Ir(2-phq)2(acac) (Bis(2-phenylquinoline)(acetylacetonate)iridium(III)), Hex-Ir(phq)₂ (acac) (Bis [2-(4-n-hexylphenyl)quinoline](acetylacetonate)iridium(III)), Hex-Ir(phq)₃ (Tris [2-(4-n-hexylphenyl)quinoline)]iridium(III)), Ir(dpm)PQ₂ (Bis(2-phenylquinoline)(2,2,6,6-tetramethylheptane-3,5-dionate)iridium(III)) or other suitable dopant materials. It should be noted that, although the first organic light emitting layer 161 disclosed in the present embodiment is mainly composed of one single organic light emitting material, it may inevitably contain traces of unwanted impurities or the like.

The pixel structure of the electroluminescent display panel 100 according to the present embodiment may further include a third sub-pixel region P3. The pixel structure of the electroluminescent display panel 100 may include a third anode 123, a third cathode 183, a second organic light emitting layer 162 and a substrate 110. The third anode 123, the third cathode 183 and the second organic light emitting layer 162 are all disposed in the third sub-pixel region P3. The first anode 121, the second anode 122, the third anode 123, the first cathode 181, the second cathode 182 and the third cathode 183 are all disposed on the substrate 110. The second organic light emitting layer 162 is a single layered organic light emitting layer composed of one single organic light emitting material so that third primary color light L3 may be generated from the third sub-pixel region P3. For example, when the first primary color light L1 is green light and the second primary color light L2 is red light, the organic light emitting material of the second organic light emitting layer 162 is preferably composed of blue organic light emitting material, and the third primary color light L3 is blue light, but not limited to this. In other words, the pixel structure of the electroluminescent display panel 100 may include the first sub-pixel region P1, the second sub-pixel region P2 and the third sub-pixel region P3. These three regions may respectively emit different color lights. The first sub-pixel region P1, the second sub-pixel region P2 and the third sub-pixel region P3 may be arranged side-by-side. In this configuration, the first sub-pixel region P1 is disposed adjacent to the second sub-pixel region P2 and the first sub-pixel region P1 is also disposed adjacent to the third sub-pixel region P3, but not limited to this. One feature of the pixel structure of the electroluminescent display panel 100 disclosed in the present embodiment is that green light, red light and blue light may be respectively emitted from the first sub-pixel region P1, the second sub-pixel region P2 and the third sub-pixel region P3 by using only two different single organic light emitting materials that respectively comprise the first organic light emitting layer 161 and the second organic light emitting layer 162. In this way, the full-color display can be achieved through properly mixing green light, red light and blue light emitted from these three regions. It should be noted that a third micro cavity C3 is formed between the third anode 123 and the third cathode 183 in the third sub-pixel region P3. The cavity length of the third micro cavity C3 is preferably shorter than the cavity length of the first micro cavity C1, but not limited to this.

As shown in FIG. 1, the pixel structure of the electroluminescent display panel 100 according to this embodiment may further include a first hole injection layer 141, a second hole injection layer 142, a third hole injection layer 143, a fourth hole injection layer 144, a fifth hole injection layer 145, a sixth hole injection layer 146, a first hole transporting layer 151, a second hole transporting layer 152, a third hole transporting layer 153 and an electron transporting layer 170. The third hole injection layer 143, the first hole injection layer 141 and the first hole transporting layer 151 are all disposed in the first sub-pixel region P1 and are sequentially stacked between the first anode 121 and the first organic light emitting layer 161. The fourth hole injection layer 144, the second hole injection layer 142 and the second hole transporting layer 152 are all disposed in the second sub-pixel region P2 and are sequentially stacked between the second anode 122 and the first organic light emitting layer 161. The sixth hole injection layer 146, the fifth hole injection layer 145 and the third hole transporting layer 153 are all disposed in third sub-pixel region P3 and are sequentially stacked between the third anode 123 and the second organic light emitting layer 162. The electron transporting layer 170 is disposed in the first sub-pixel region P1, the second sub-pixel region P2 and the third sub-pixel region P3, and is respectively located between the first organic light emitting layer 161 and the first cathode 181, between the first organic light emitting layer 161 and the second cathode 182, and between the second organic light emitting layer 162 and the third cathode 183. It should be noted that two hole injection layers in each of the sub-pixel regions, such as the first hole injection layer 141 and the third hole injection layer 143 in the first sub-pixel region P1, may be used to modify electrical properties of each sub-pixel so as to obtain required light emitting effects. The composition of these two hole injection layers in each sub-pixel region may be the same or different based on different design requirements. For example, the third hole injection layer 143, the fourth hole injection layer 144 and the sixth hole injection layer 146 may preferably include Copper Phthalocyanine (CuPc), poly-3,4-ethylenedioxythiophene (PEDOT), 4,4′,4″-tris-N-naphthyl-N-Phenylaminoutriphenylamine (TNATA), Hexanitrile hexaazatriphenylene (HAT), Dipyrazino [2,3-f:2′,3′-h]quinoxaline-2,3,6,7,10,11-hexacarbonitrile (HAT-CN), N,N,N′,N′-tetrakis(4-methoxyphenyl)benzidine (MeO-TPD) or other suitable material. The first hole injection layer 141, the second hole injection layer 142 and the fifth hole injection layer 145 may preferably may include N,N′-bis(naphthalen-1-yl)-N,N′-bis(phenyl)-benzidine (NPB), N,N′-bis(3-methylphenyl)-N,N′-bis(phenyl)-benzidine (TPD), N,N′-bis(naphthalen-1-yl)-N,N′-bis(phenyl)-9,9-spirobifluorene (Spiro-NPB), Di[4-(N,N-ditolyl-amino)-phenyl]cyclohexane (TAPC), N,N,N′,N′-tetra-naphthalenyl-benzidine (α-TNB) or other suitable material.

It should be noted that, according to this embodiment, the difference in the cavity lengths among the first micro cavity C1, the second micro cavity C2 and the third micro cavity C3 is preferably achieved through the first hole injection layer 141, the second hole injection layer 142 and the fifth hole injection layer 145 be of different thicknesses. In other words, the thickness of the second hole injection layer 142 is preferably thicker than the thickness of the first hole injection layer 141, and the thickness of first hole injection layer 141 is preferably thicker than the thickness of the fifth hole injection layer 145, but not limited to this. In addition, the third hole injection layer 143, the fourth hole injection layer 144 and the sixth hole injection layer 146 preferably have the same thickness in order to simplify manufacturing processes, but not limited to this. For example, the thickness of the first hole injection layer 141 preferably ranges from 120 nanometers to 150 nanometers, and the thickness of the second hole injection layer 142 preferably ranges from 170 nanometers to 220 nanometers in order to achieve the required cavity lengths. For example, in the pixel structure of the electroluminescent display panel 100 disclosed in this embodiment, when the thickness of the first hole injection layer 141 is substantially set at 135 nanometers and the thickness of the second hole injection layer 142 is substantially set at 205 nanometers, green light (i.e. the first primary color light L1) having a light intensity of approximately 95.9 LM and a color coordinate (0.245, 0.719) in CIE chart, and red light (i.e. the second primary color light L2) having a light intensity of approximately 19.1 LM and a color coordinate (0.651, 0.347) in CIE chart, may be emitted from this configuration. According to other preferred embodiments of the present invention, the thickness of the first hole transporting layer 151, the second hole transporting layer 152 and the third hole transporting layer 153 or the thickness of the electron transporting layer 170 in each sub-pixel region may be adjusted if required, in order to obtain different cavity lengths for the first micro cavity C1, the second micro cavity C2 and the third micro cavity C3.

The pixel structure of the electroluminescent display panel 100 according to this embodiment may further include a first transparent electrode layer 131, a second transparent electrode layer 132 and a third transparent electrode layer 133, which are respectively disposed in the first sub-pixel region P1, the second sub-pixel region P2 and the third sub-pixel region P3, to improve the coherence between each anode and each corresponding hole injection layer, but not limited to this. Additionally, according to this embodiment, the first cathode 181, the second cathode 182 and the third cathode 183 may preferably respectively include a transflective electrode. The first anode 121, the second anode 122 and the third anode 123 may preferably respectively include a reflective electrode. In this configuration, the first primary color light L1, the second primary color light L2 and the third primary color light L3 may be emitted upwardly. Therefore, the electroluminescent display panel disclosed in this embodiment may be regarded as a top emission type electroluminescent display panel, but not limited to this.

In the following paragraph, various embodiments are disclosed and the description below is mainly focused on differences among each embodiment. In addition, like or similar features will usually be described with same reference numerals for ease of illustration and description thereof

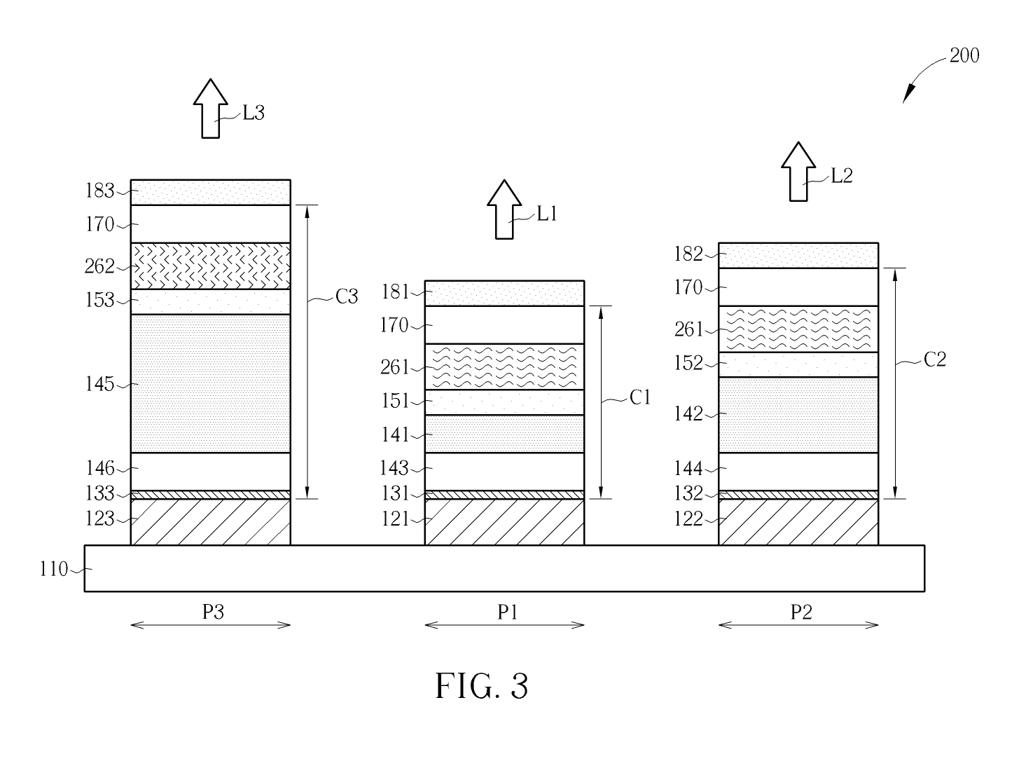

Please refer to FIG. 3. FIG. 3 is a schematic diagram showing a pixel structure of an electroluminescent display panel 200 according to the second preferred embodiment of the present invention. As shown in FIG. 3, one main difference between this embodiment and the first preferred embodiment is that the pixel structure of an electroluminescent display panel 200 includes the first organic light emitting layer 261 disposed in the first sub-pixel region P1 and the second sub-pixel region P2. The first organic light emitting layer 261 is a single layered organic light emitting layer made of one single organic light emitting material. Through the first organic light emitting layer 261, the first primary color light L1 and the second primary color light L2 may be respectively generated from the first sub-pixel region P1 and the second sub-pixel region P2. The organic light emitting material of the first organic light emitting layer 261 according to this embodiment is preferably a blue-green organic light emitting material. The first primary color light L1 is blue light and the second primary color light L2 is green light, but not limited to this. Additionally, the peak wavelength of the blue green organic light emitting material according to this embodiment preferably ranges from 475 nanometers to 495 nanometers, but not limited to this. Furthermore, the above mentioned blue-green organic light emitting material is preferably chosen from a single organic light emitting material composed of the mixture of host material and dopant material. This single organic light emitting material can only emit one single color light itself. The host material described above is preferably selected from one of the group consisting of AND (9,10-di(naphth-2-yl)anthracene), TSBF (2,7-bis(9,9-spirobifluoren-2-yl)-9,9-spirobifluorene), 2,2′-Spiro-Pye(2,2′-dipyrenyl-9,9-spirobifluorene), BPPF (9,9-bis[4-(pyrenyl)phenyl]-9H-fluorene) or other suitable host material. The dopant material described above is preferably selected from one of the group consisting of Spiro-BDAVBi (2,7-bis[4-(diphenylamino)styryl]-9,9-spirobifluorene, DSA-Ph (1-4-di-[4-(N,N-diphenyl)amino]styryl-benzene) or other suitable dopant materials. It should be noted that, although the first organic light emitting layer 261 disclosed in the present embodiment is mainly composed of one single organic light emitting material, it may inevitably contain traces of unwanted impuruties or the like. Additionally, the pixel structure of the electroluminescent display panel 200 according to the present embodiment may further include a second organic light emitting layer 262 disposed in the third sub-pixel region P3. The second organic light emitting layer 262 is a single layered organic light emitting layer composed of one single organic light emitting material so that third primary color light L3 may be generated from the third sub-pixel region P3. For example, when the first primary color light L1 is blue light and the second primary color light L2 is green light, the organic light emitting material of the second organic light emitting layer 262 is preferably composed of a red organic light emitting material, and the third primary color light L3 is preferably red light, but not limited to this. In other words, green light, red light and blue light may be respectively emitted from the first sub-pixel region P1, the second sub-pixel region P2 and the third sub-pixel region P3 by using only two different single organic light emitting materials that respectively comprise the first organic light emitting layer 261 and the second organic light emitting layer 262. In this way, a full-color display effect can be achieved through properly mixing green light, red light and blue light emitted from these three regions. It should be noted that the cavity length of the first micro cavity C1 is preferably shorter than the cavity length of the second micro cavity C2, and the cavity length of the second micro cavity C2 is preferably shorter than the cavity length of the third micro cavity C3 so as to enable the first sub-pixel region P1, the second sub-pixel region P2 and the third sub-pixel region P3 to respectively provide the first primary color light L1, the second primary color light L2 and the third primary color light L3.

It should be noted that, according to this embodiment, the difference of the cavity lengths among the first micro cavity C1, the second micro cavity C2 and the third micro cavity C3 is preferably achieved through the first hole injection layer 141, the second hole injection layer 142 and the fifth hole injection layer 145 having different thicknesses. One main difference between this embodiment and the first preferred embodiment is that the thickness of the second hole injection layer 142 is preferably thicker than the thickness of the first hole injection layer 141, and the thickness of the fifth hole injection layer 145 is preferably thicker than the thickness of the second hole injection layer 142. In this configuration, the cavity length of the first micro cavity C1 may be shorter than the cavity length of the second micro cavity C2, and the cavity length of the second micro cavity C2 is shorter than the cavity length of the third micro cavity C3. In addition, the third hole injection layer 143, the fourth hole injection layer 144 and the sixth hole injection layer 146 are preferably in the same thickness in order to simplify manufacturing processes, but not limited to this. According to this embodiment, the thickness of the first hole injection layer 141 may preferably range from 75 nanometers to 110 nanometers, and the thickness of the second hole injection layer 142 may preferably range from 120 nanometers to 150 nanometers in order to achieve required cavity length. For example, in the pixel structure of the electroluminescent display panel 200 disclosed in this embodiment, when the thickness of the first hole injection layer 141 is substantially set at 90 nanometers and the thickness of the second hole injection layer 142 is substantially set at 145 nanometers, blue light (i.e. first primary color light L1) having a light intensity of approximately 5.3 LM and a color coordinate (0.114, 0.175) in CIE chart, and green light (i.e. second primary color light L2) with a light intensity of approximately 114 LM and a color coordinate (0.209, 0.726) in CIE chart, may be emitted from this configuration. Apart from the modification of the first organic light emitting layer 261, the second organic light emitting layer 262 and the cavity length of each micro cavity, the rest of the parts of the pixel structure of the electroluminescent display panel 200 disclosed in this embodiment, such as positions of other parts, material properties, optical properties and means of radiation are almost similar to those shown in the pixel structure of the electroluminescent display panel 100 disclosed in the previous first preferred embodiment. For the sake of brevity, these similar configurations and properties are therefore not disclosed in detail.

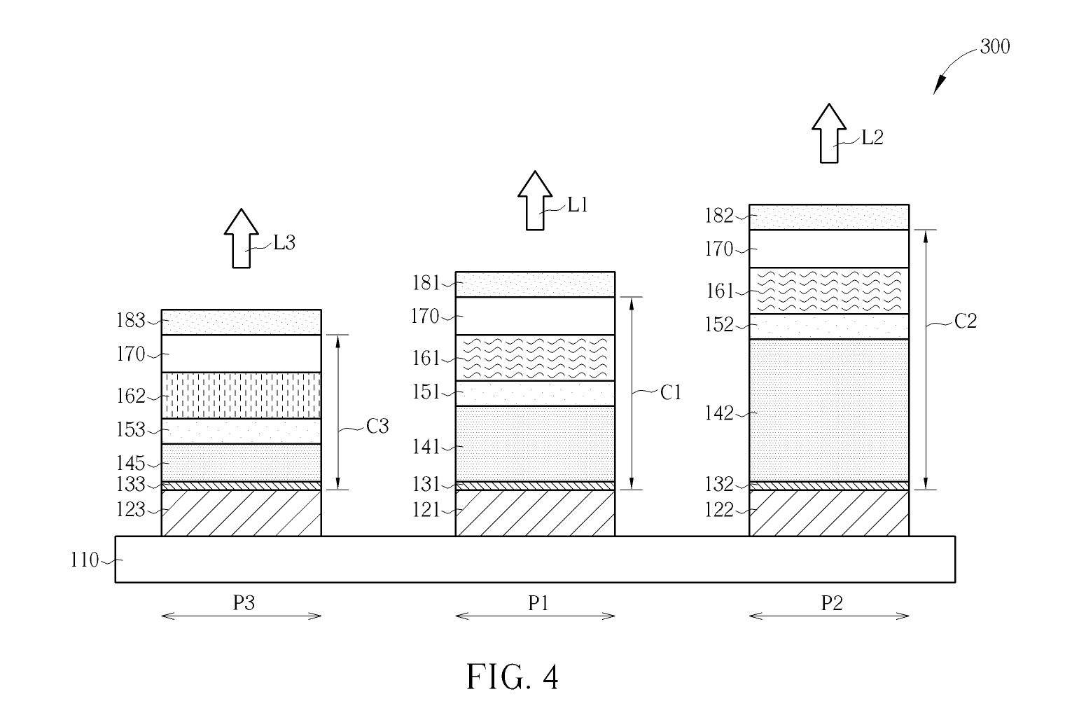

FIG. 4 is a schematic diagram showing a pixel structure of an electroluminescent display panel according to the third preferred embodiment of the present invention. As shown in FIG. 4, one main difference between this embodiment and the first preferred embodiment is that each sub-pixel of the pixel structure of an electroluminescent display panel 300 only includes a single layered hole injection layer. That is to say, the pixel structure of the electroluminescent display panel 300 disclosed in this embodiment does not include the above-mentioned third hole injection layer, fourth hole injection layer, and sixth hole injection layer. In this way, the corresponding configuration can be simplified accordingly. It should be noted that, according to this embodiment, the difference of the cavity lengths among the first micro cavity C1, the second micro cavity C2 and the third micro cavity C3 is preferably achieved through the first hole injection layer 141, the second hole injection layer 142 and the fifth hole injection layer 145 having different thicknesses, but not limited to this. According to other preferred embodiments of the present invention, the thickness of the first hole transporting layer 151, the second hole transporting layer 152, the third hole transporting layer 153, the first transparent electrode layer 131, the second transparent electrode layer 132 and the third transparent electrode layer 133 or the thickness of the electron transporting layer 170 in each sub-pixel region may be adjusted if required, in order to have the first micro cavity C1, the second micro cavity C2 and the third micro cavity C3 with different cavity lengths.

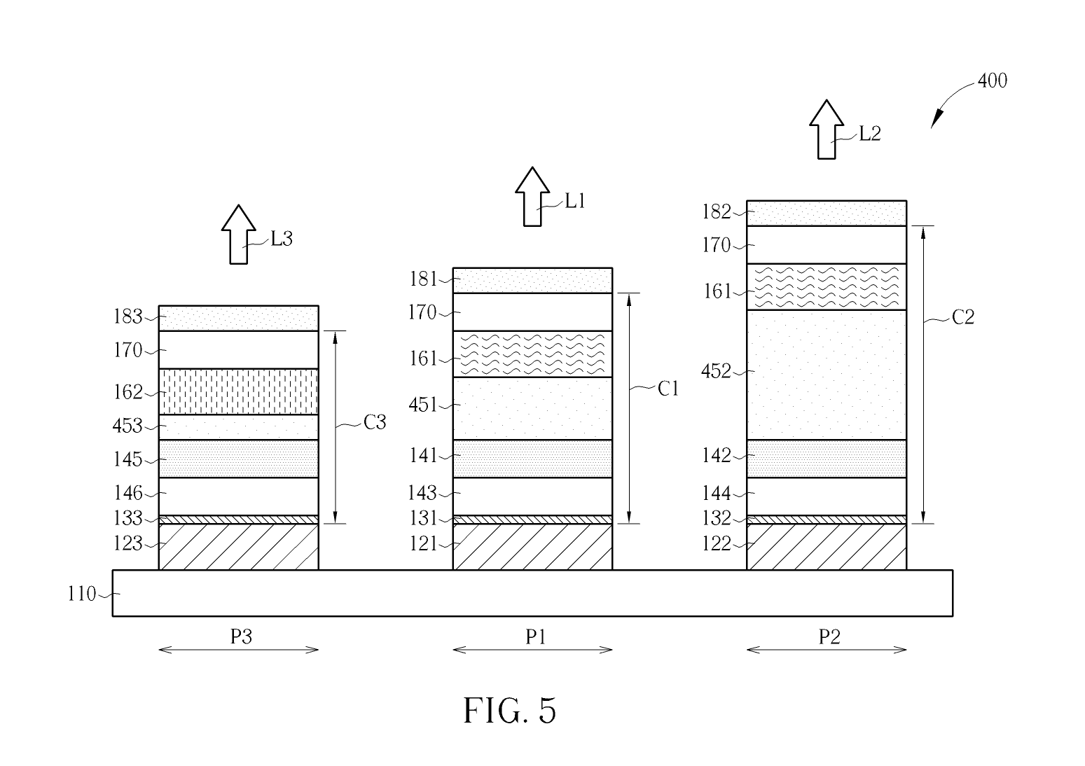

FIG. 5 is a schematic diagram showing a pixel structure of an electroluminescent display panel 400 according to the fourth preferred embodiment of the present invention. As shown in FIG. 5, one main difference between this embodiment and the first preferred embodiment is that the pixel structure of the electroluminescent display panel 400 includes a first hole transporting layer 451, a second hole transporting layer 452 and a third hole transporting layer 453 respectively disposed in the first sub-pixel region P1, the second sub-pixel region P2 and the third sub-pixel region P3. According to this embodiment, the difference of the cavity length among the first micro cavity C1, the second micro cavity C2 and the third micro cavity C3 is preferably achieved through providing the first hole transporting layer 451, the second hole transporting layer 452 and the third hole transporting layer 453 with different thicknesses. In addition, the first hole injection layer 141, the second hole injection layer 142 and the fifth hole injection layer 145 preferably have the same thickness in order to simplify the manufacturing processes, but not limited to this.

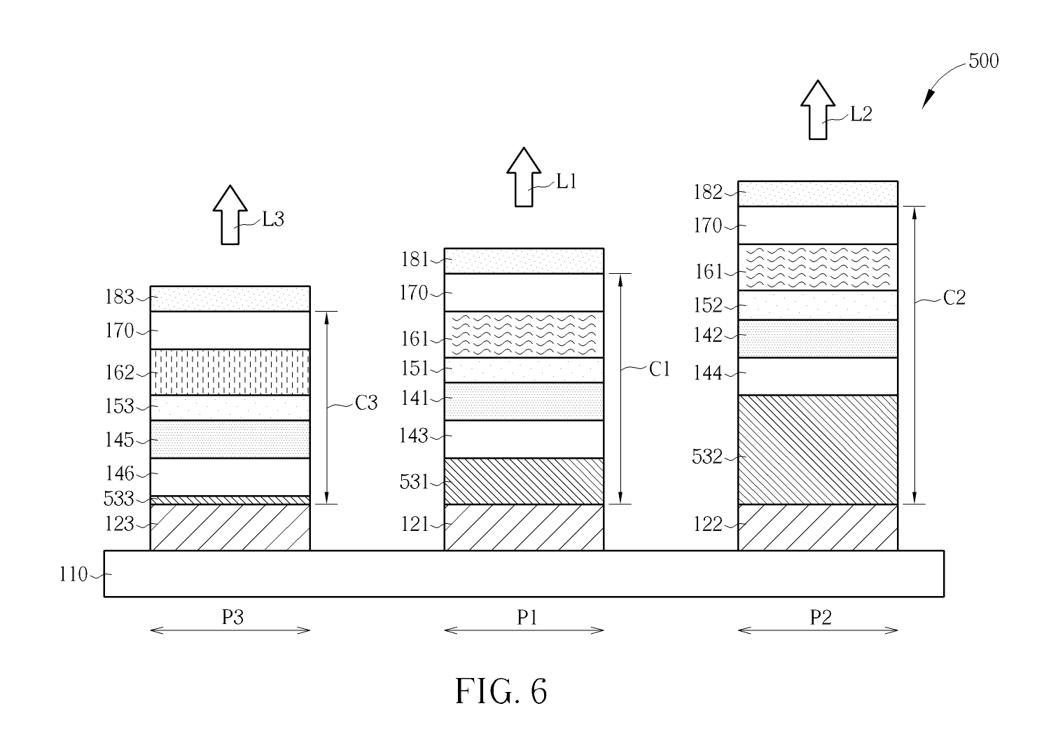

FIG. 6 is a schematic diagram showing a pixel structure of an electroluminescent display panel 500 according to the fifth preferred embodiment of the present invention. As shown in FIG. 6, one main difference between this embodiment and the first preferred embodiment is that the pixel structure of the electroluminescent display panel 600 includes a first transparent electrode layer 531, a second transparent electrode layer 532 and a third transparent electrode layer 533 respectively disposed in the first sub-pixel region P1, the second sub-pixel region P2 and the third sub-pixel region P3. It should be noted that, according to this embodiment, the difference of the cavity length among the first micro cavity C1, the second micro cavity C2 and the third micro cavity C3 is preferably achieved through providing the first transparent electrode layer 531, the second transparent electrode layer 532 and the third transparent electrode layer 533 with different thicknesses. In addition, the first hole injection layer 141, the second hole injection layer 142 and the fifth hole injection layer 145 preferably have the same thickness in order to simplify the manufacturing processes, but not limited to this.

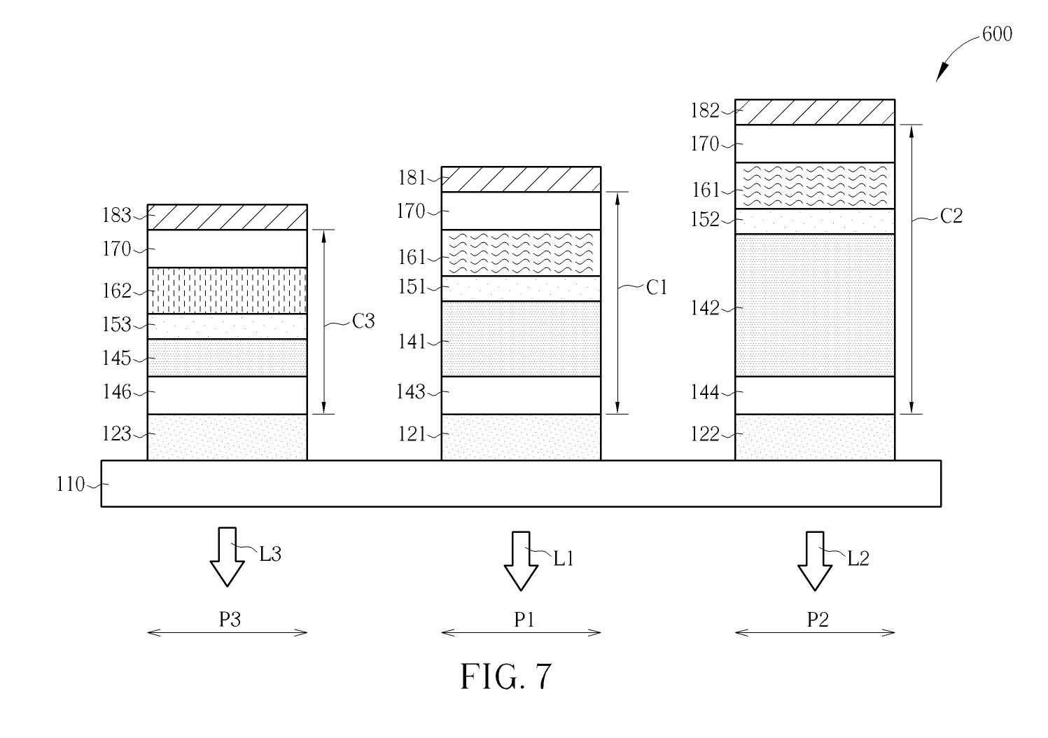

Please refer to FIG. 7. FIG. 7 is a schematic diagram showing a pixel structure of an electroluminescent display panel 600 according to the sixth preferred embodiment of the present invention. As shown in FIG. 7, one main difference between this embodiment and the first preferred embodiment is that, in the pixel structure of the electroluminescent display panel 600, the first anode 121, the second anode 122 and the third anode 123 may preferably respectively include a transflective electrode. The first cathode 181, the second cathode 182 and the third cathode 183 may preferably respectively include a reflective electrode. In this configuration, the first primary color light L1, the second primary color light L2 and the third primary color light L3 may be emitted downwardly. Therefore, the electroluminescent display panel disclosed in this embodiment may be regarded as a bottom emission type electroluminescent display panel, but not limited to this.

To summarize, based on the micro cavity effect and by disposing organic light emitting layers composed of one single organic light emitting material in respective sub-pixel regions with different cavity lengths, different primary color light can be respectively generated from different sub-pixel regions of the pixel structure of the electroluminescent display panel in the present invention. In this way, the manufacturing processes and the configurations of the display can be simplified, which further lowers the manufacturing costs. Additionally, since three sub-pixel regions with different primary color lights can be obtained through using only two different single organic light emitting materials that respectively comprise the corresponding organic light emitting layers, the saturation of the display can be improved consequently and the power consumption is also reduced effectively.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A pixel structure of an electroluminescent display panel, comprising a first sub-pixel region and a second sub-pixel region, the pixel structure of the electroluminescent display panel comprising:
a first anode, disposed in the first sub-pixel region;
a second anode, disposed in the second sub-pixel region;
a first organic light emitting layer, disposed in the first sub-pixel region and the second sub-pixel region, wherein the first organic light emitting layer is a single layered organic light emitting layer, and the first organic light emitting layer is substantially composed of one single organic light emitting material for the first sub-pixel region and the second sub-pixel region respectively generating a first primary color light and a second primary color light;
a first cathode, disposed in the first sub-pixel region; and
a second cathode, disposed in the second sub-pixel region, wherein a first micro cavity is formed between the first anode and the first cathode in the first sub-pixel region, and a second micro cavity is formed between the second anode and the second cathode in the second sub-pixel region, wherein a cavity length of the first micro cavity is shorter than a cavity length of the second micro cavity so as to enable the first sub-pixel region to provide the first primary color light and enable the second sub-pixel region to provide the second primary color light, and a peak wavelength of the second primary color light is larger than a peak wavelength of the first primary color light.

2. The pixel structure of claim 1, wherein the organic light emitting material of the first organic light emitting layer is a yellow organic light emitting material, and a color of the first primary color light is green and a color of the second primary color light is red.

3. The pixel structure of claim 2, further comprising a third sub-pixel region, and the pixel structure further comprising:
a third anode, disposed in the third sub-pixel region;
a third cathode, disposed in the third sub-pixel region; and
a second organic light emitting layer, disposed in the third sub-pixel region, wherein the second organic light emitting layer is a single layered organic light emitting layer, and the second organic light emitting layer is substantially composed of one single organic light emitting material so as to provide a third primary color light generated by the third sub-pixel region.

4. The pixel structure of claim 3, wherein the organic light emitting material of the second organic light emitting layer is a blue organic light emitting material, and a color of the third primary color light is blue.

5. The pixel structure of claim 1, wherein the organic light emitting material of the first organic light emitting layer is a blue-green organic light emitting material, and a color of the first primary color light is blue and a color of the second primary color light is green.

6. The pixel structure of claim 5, further comprising a third sub-pixel region, and the pixel structure further comprising:
a third anode, disposed in the third sub-pixel region;
a third cathode, disposed in the third sub-pixel region; and
a second organic light emitting layer, disposed in the third sub-pixel region, wherein the second organic light emitting layer is a single layered organic light emitting layer, and the second organic light emitting layer is substantially composed of one single organic light emitting material so as to provide a third primary color light generated by the third sub-pixel region.

7. The pixel structure of claim 6, wherein the organic light emitting material of the second organic light emitting layer is a red organic light emitting material, and a color of the third primary color light is red.

8. The pixel structure of claim 1, further comprising:
a first hole injection layer, disposed in the first sub-pixel region; and
a second hole injection layer, disposed in the second sub-pixel region,
wherein a thickness of the first hole injection layer is thinner than a thickness of the second hole injection layer so that the cavity length of the first micro cavity is shorter than the cavity length of the second micro cavity.

9. The pixel structure of claim 8, wherein the thickness of the first hole injection layer substantially ranges from 120 nanometers to 150 nanometers, and the thickness of the second hole injection layer substantially ranges from 170 nanometers to 220 nanometers.

10. The pixel structure of claim 8, wherein the thickness of the first hole injection layer substantially ranges from 75 nanometers to 110 nanometers, and the thickness of the second hole injection layer substantially ranges from 120 nanometers to 150 nanometers.

11. The pixel structure of claim 8, further comprising:
a third hole injection layer disposed in the first sub-pixel region; and
a fourth hole injection layer disposed in the second sub-pixel region, wherein a thickness of the third hole injection layer is substantially equal to a thickness of the fourth hole injection layer.

12. The pixel structure of claim 1, wherein the electroluminescent display panel is a top emission type electroluminescent display panel, the first cathode and the second cathode respectively comprise a transflective electrode, and the first anode and the second anode respectively comprise a reflective electrode.

13. The pixel structure of claim 1, wherein the electroluminescent display panel is a bottom emission type electroluminescent display panel, the first anode and the second anode respectively comprise a transflective electrode, and the first cathode and the second cathode respectively comprise a reflective electrode.

14. The pixel structure of claim 2, wherein a peak wavelength of a light spectrum of the yellow organic light emitting material substantially ranges from 575 nanometers to 595 nanometers.

15. The pixel structure of claim 5, wherein a peak wavelength of a light spectrum of the blue-green organic light emitting material substantially ranges from 475 nanometers to 495 nanometers.

16. The pixel structure of claim 1, further comprising:
a first hole transporting layer disposed in the first sub-pixel region; and
a second hole transporting layer disposed in the second sub-pixel region, wherein a thickness of the first hole transporting layer is thinner than a thickness of the second hole transporting layer so that the cavity length of the first micro cavity is shorter than the cavity length of second micro cavity.

17. The pixel structure of claim 1, further comprising:
a first transparent electrode layer disposed in the first sub-pixel region; and
a second transparent electrode layer disposed in the second sub-pixel region, wherein a thickness of the first transparent electrode layer is thinner than a thickness of the second transparent electrode layer so that the cavity length of the first micro cavity is shorter than the cavity length of the second micro cavity.
